(19) United States
(12) Patent Application Publication
(10) Pub. No.: US 2026/0358394 A1
(43) Pub. Date: Nov. 12, 2026

(54) APPARATUS AND METHOD FOR RAPID MULTI-TURN INDUCTANCE CHARACTERIZATION OF MAGNETIC CORES

(71) Applicant: Schweitzer Engineering Laboratories, Inc., Pullman, WA (US)

(72) Inventor: Cory James Bakeman, Palouse, WA (US)

(73) Assignee: Schweitzer Engineering Laboratories, Inc., Pullman, WA (US)

(21) Appl. No.: 19/200,933

(22) Filed: May 7, 2025

(51) Int. Cl. G01R 27/26

(52) U.S. Cl. CPC G01R 27/2611

(57) ABSTRACT

Various examples of apparatuses and methods of use are disclosed for rapid multi-turn electrical characterization of a magnetic core, such as a toroid. In various examples, a support structure defines a core-receiving region between two opposing probe carriers with electrically conductive contact probes. Conductors externally connect paired probes with respect to the opening in the core. The carriers can be moved between an open position and a closed position. In the closed measurement position, the engaged probes and jumpers cooperate to form a predetermined number of conductive loops or turns through the core. The loops or turns end at opposing terminals or leads that can be connected to an LCR measurement device. In various examples, the actuation apparatus comprises a manual slide, integrated pneumatics, and/or an electrical motor. Methods for measurement include loading the core, closing the carriers, and measuring inductance or other parameters.

### TECHNICAL FIELD

This disclosure relates generally to apparatuses and methods for characterizing magnetic cores. More specifically, this disclosure relates to fixtures that enable rapid, multi-turn inductance measurement of toroidal magnetic cores using LCR instrumentation.

### BRIEF DESCRIPTION OF THE DRAWINGS

FIG. 1 illustrates a magnetic core with a plurality of loops or turns, according to one embodiment.

FIG. 2A illustrates a manually actuated apparatus that creates a multi-turn test path through a magnetic core, according to one embodiment.

FIG. 2B illustrates a side elevational view of the apparatus of FIG. 2A, according to one embodiment.

FIG. 2C illustrates a top view of a manually actuated apparatus, according to one embodiment.

FIG. 2D is an end view of the apparatus with a clear depiction of the guide rails of the support structure, according to one embodiment.

FIG. 3A is a perspective view of a manually actuated apparatus with a set of conductors positioned externally to the core-receiving region, according to one embodiment.

FIG. 3B is an enlarged view of a single contact probe as might be retained in a probe carrier, according to one embodiment.

FIG. 3C depicts an example of a toroidal magnetic core, according to one embodiment.

FIG. 3D depicts the manually actuated apparatus of FIG. 3A with the toroidal magnetic core positioned within the core-receiving region, according to one embodiment.

FIG. 3E shows the manually actuated apparatus of FIG. 3A with the right probe carrier translated laterally into the closed measurement position, according to one embodiment.

FIG. 4A is a perspective view of an automated actuation apparatus to translate two opposing probe carriers relative to a core-receiving region, according to one embodiment.

FIG. 4B is a perspective view of the apparatus of FIG. 4A with an example of a toroidal magnetic core positioned in the core-receiving region, according to one embodiment.

FIG. 4C illustrates the apparatus in an intermediate position reached after the first stage of actuation or partial actuation, according to one embodiment.

FIG. 4D shows the apparatus in the closed measurement position, according to one embodiment.

FIG. 4E depicts the apparatus in the open loading position with a toroidal magnetic core seated on a nest plate, according to one embodiment.

FIG. 4F shows the apparatus in the closed measurement position, according to one embodiment.

FIG. 5 depicts an automated apparatus with a pneumatic actuation subsystem, according to one embodiment.

FIG. 6 shows an automated apparatus that utilizes a rotary drive assembly, according to one embodiment.

FIG. 7 illustrates an apparatus to characterize a toroidal magnetic core that has already been wound with a production winding, according to one embodiment.

FIG. 8 illustrates an apparatus that employs triangular frameworks, according to one embodiment.

### DETAILED DESCRIPTION

Magnetic cores, such as toroidal magnetic cores, are routinely incorporated into inductors, current transformers, and other power-conversion components. Manufacturers may verify core performance by measuring various characteristics, such as inductance, with an LCR meter. Measurement accuracy is very limited with only one turn or loop of wire through the magnetic core. Accurate readings are typically attained by using multiple wire turns through the core opening.

One technique to measure accurate LCR characteristics is to hand-wind seven to ten loops of loose wire around each core, connect the wire ends to the LCR leads, and record the measurement. This procedure is slow, it varies with operator skill, and it accelerates wear on both the test wire and the meter leads.

According to various embodiments of the presently described systems and methods, a pre-wired network of spring-loaded contact probes is permanently attached to an LCR meter. An operator or machine places the magnetic core, such as the toroidal core, in a recessed support between opposing probe carriers, each of which includes an array of contact probes. The operator or machine slides or otherwise translates the probe carriers together. The spring-loaded contact probes mate and, together with the pre-wired network of external jumpers, instantly create a multi-turn path through the magnetic core with pre-connected electrical terminals connected to the LCR machine. LCR measurements of a toroidal core can be completed very quickly (e.g., seconds or less) without any manual wire winding.

In various embodiments, the contact probes are connected by the conductors or jumpers outside the core opening. The contact probes may be positioned very close together and/or centered with the core opening. Accordingly, the apparatus accommodates wound or potted cores and can be scaled for various sizes of toroidal cores and/or magnetic cores of various shapes. Manual, pneumatic, and/or motor actuation options are described herein.

The embodiments of the disclosure can be understood by reference to the drawings, wherein like parts are designated by like numerals throughout. The components of the disclosed embodiments, as generally described and illustrated in the figures herein, could be arranged and designed in a wide variety of different configurations. Thus, the following detailed description of the embodiments of the systems and methods of the disclosure is not intended to limit the scope of the disclosure, as claimed, but is merely representative of possible embodiments of the disclosure. In addition, the steps of a method do not necessarily need to be executed in any specific order or even sequentially, nor do the steps need to be executed only once unless otherwise specified.

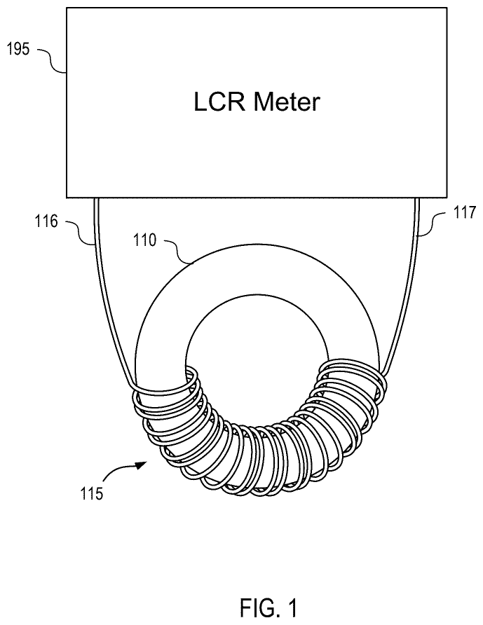

FIG. 1 illustrates a magnetic core 110, shown as a toroidal magnetic core, with a plurality of loops or turns formed around the core by a conductor 115, according to one embodiment. The conductor 115 is threaded through the core aperture to achieve a suitable number of turns for acceptable LCR-meter accuracy. The opposite ends of the wound conductor 115 are referred to as the electrical terminals 116 and 117 or leads. The electrical terminals 116 and 117 are connected to an LCR meter 195. The LCR meter 195 is an example of a magnetic core characterization device. The magnetic core characterization device may characterize the inductance (L), capacitance (C), and/or resistance (R) of the toroidal magnetic core 110. In various embodiments, an LCR meter 195 or other magnetic core characterization device may be used to determine one or more electrical parameters of the magnetic core. Examples of electrical parameters that might be determined, calculated, or measured using the system and methods described herein include but are not limited to inductance (L), permeability (e.g., based on a known number of turns, and geometry), an impedance magnitude, a quality factor, a dissipation factor, series and/or parallel equivalent capacitance, complex permeability components (e.g., based on the inductance and loss data for specific core dimensions), core loss or effective series resistance (ESR), and/or other electrical, magnetic, resonance, frequency, or harmonic parameters.

As previously described, hand-winding the conductor 115 for testing purposes can be time-consuming. Moreover, re-using the same wire for repeated tests can degrade the insulation and contact reliability, and repeatedly coupling electrical terminals 116 and 117 to the LCR meter 195 can accelerate wear. Variations in turn tension, spacing, and overlap further reduce repeatability, making it difficult to compare measurement data across production lots or between operators.

The systems and methods described herein overcome these shortcomings by eliminating manual winding, providing opposed probe carriers that automatically form a repeatable multi-turn conductive path through the core, and maintaining constant (e.g., permanent or semi-permanent) connections to the LCR meter. As detailed herein, the presently described systems and methods allow an operator (or automated handler, such as a robot or robotic machine) to place a core in a core-receiving region. The operator actuates the probe carriers (e.g., manually, pneumatically, via a motor, or the like) to close the contact probes. In various embodiments, spring-biased contact probes engage with consistent contact force, external jumpers (conductors) complete the series loops (e.g., equivalent to turns around the core), and LCR measurement(s) are taken in seconds or even a fraction of a second. The apparatuses and associated methods described herein increase throughput, improve measurement consistency, reduce consumable cost, and reduce mechanical wear on test leads.

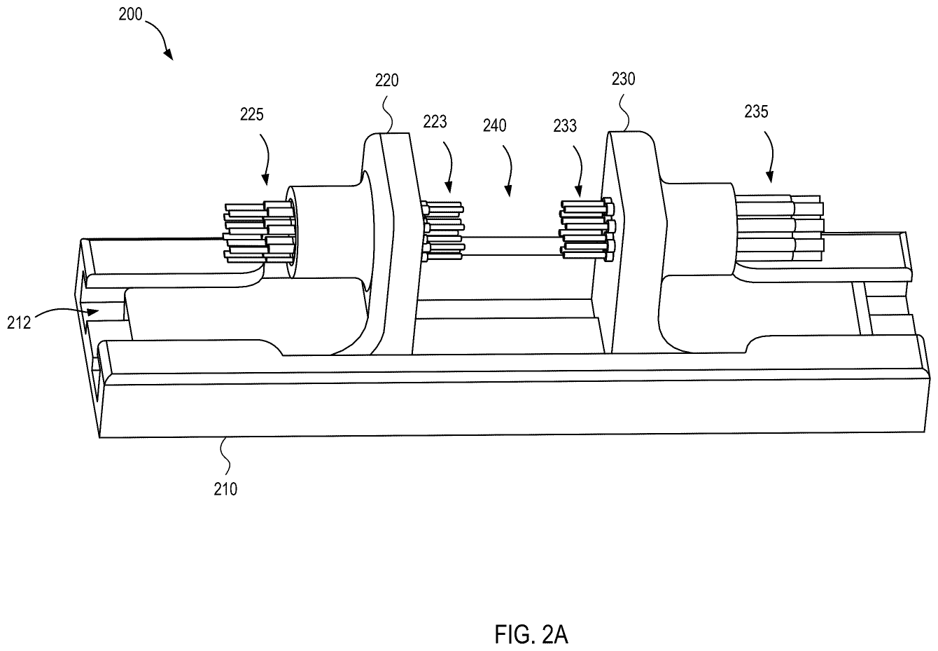

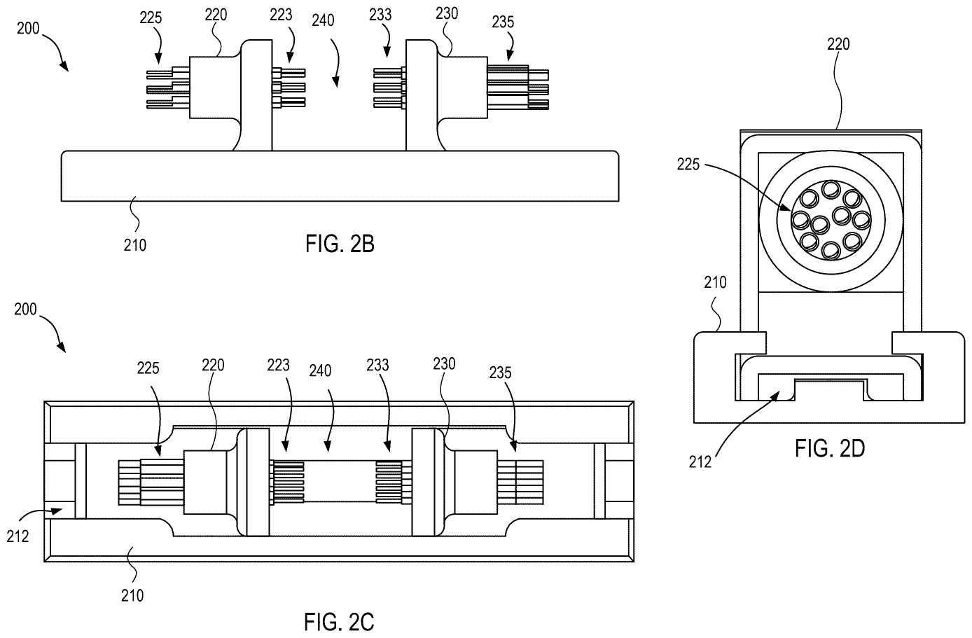

FIG. 2A illustrates a manually actuated apparatus 200 that quickly establishes a multi-turn test path through a magnetic core, according to one embodiment. A slide-base support structure 210 includes channels and integral guide rails 212 to control the translational movement of opposing probe carriers 220 and 230. As illustrated, the apparatus 200 includes a left probe carrier 220 and a right probe carrier 230 that can be manually translated toward and away from one another along a linear axis.

The left probe carrier 220 includes a first set of electrically conductive contact probes 223 that are oriented toward a core-receiving region 240 of the apparatus 200. More specifically, each contact probe includes a mating end oriented toward the core-receiving region 240. The mating end may, for example, comprise a spring-loaded contact tip to enhance the mechanical and electrical connection with the opposing contact probes 233 of the right probe carrier 230.

The right probe carrier 230 includes a second set of electrically conductive contact probes 223 that are oriented toward the core-receiving region 240 of the apparatus 200. Again, each contact probe includes a mating end oriented toward the core-receiving region 240, which may include a spring-loaded contact tip or other interfacing time (e.g., male/female, deformable, elastic, etc.) to enhance the mechanical and electrical connection with the opposing contact probes 223 of the left probe carrier 220.

In the illustrated example, the left probe carrier 220 includes an outward conductor stack 225 with solder-cup terminations for permanent jumper wiring. The right probe carrier 230 carries a corresponding outward conductor stack 235. When the probe carriers 220 and 230 are in the open loading position (as shown), core-receiving region 240 is unobstructed so that an operator (e.g., human or robotic operator) can place a magnetic core (e.g., a toroidal core) onto the slide-base support structure 210 and/or around one of the first or second sets of contact probes 223 or 233. Sliding the probe carriers 220 and 230 together brings the contact probes 223 and 233 into mating engagement through the opening of the magnetic core. The engagement, together with jumper conductors affixed to conductor stacks 225 and 235, are used to form multiple conductive loops that terminate at external test leads, as described herein.

FIG. 2B illustrates a side elevational view of the apparatus 200 of FIG. 2A, and uses identical reference numbers for clarity. One or both of the left probe carrier 220 and the right probe carrier 230 slide linearly along the slide-base support structure 210. The left probe carrier includes the contact probes 223 that project toward the core-receiving region 240, while the outward conductor stack 225 sits farther from the core to accept permanent jumper wiring (not visible in this view).

On the opposite side of the core-receiving region 240, the right probe carrier 230 is similarly arranged with its opposing contact probes 233 aligned opposite contact probes 223. The corresponding outward conductor stack 235 of the right probe carrier 230 is configured to accept permanent or semi-permanent jumper wiring. The side view shows that the probe carriers 220 and 230 translate closer together and farther apart along the rails of the slide-base support structure 210. As described herein, the probe carriers 220 and 230 can move between an open loading position (as illustrated in FIG. 2B) and the closed measurement position, in which the contact probes 223 and 233 engage through the opening of the magnetic core placed in the core-receiving region 240.

FIG. 2C illustrates a top view of the manually actuated apparatus 200 of FIGS. 2A and 2B. The slide-base support structure 210 is depicted as an elongated chassis with parallel guide rails 212 extending along a longitudinal axis. The left probe carrier 220 and the right probe carrier 230 ride on the guide rails 212 and are shown in the open loading position, separated by the core-receiving region 240. From above, the inward-facing rows of contact probes 223 (left probe carrier) and 233 (right probe carrier) appear as linear arrays directed toward the core-receiving region 240. The outward conductor stacks 225 and 235 are offset laterally from the region to accommodate fixed jumper wiring. As more clearly illustrated in the figures described below, with the probe carriers 220 and 230 translated along rails 212 into the closed measurement position, the conductor probes 223 and 233 mate through the central opening of a toroidal core placed in the core-receiving region 240. The mated conductor probes 223 and 233, together with the jumper wiring, form a multi-turn conductive loop, as described herein, that can be used for electrical characterization of the toroidal core.

FIG. 2D is an end view of the apparatus 200 with a clear depiction of the guide rails 212 of the slide-base support structure 210, according to one embodiment. As illustrated, the slide-base support structure 210 forms a low-profile platform, with the guide rails 212 projecting slightly above the platform surface to capture the linear bearings or rails of the probe carriers 220 and 230. The symmetry of probe carriers 220 and 230 about the core-receiving region 240 and the constrained motion provided by rails 212 ensures that the contact probes 223 and 233 engage with uniform axial alignment and contact force when the probe carriers 220 and 230 are laterally translated to the closed measurement position.

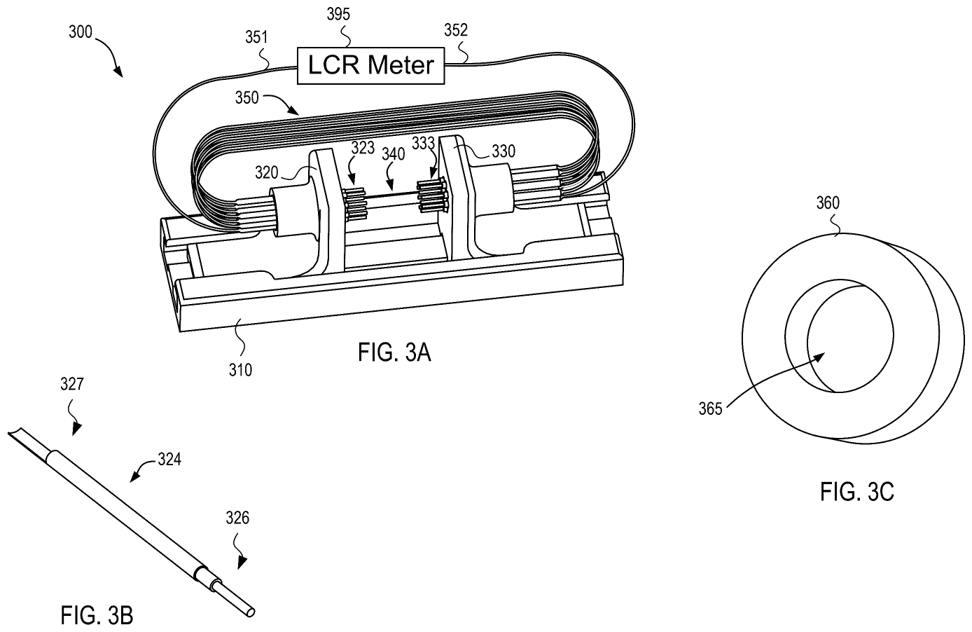

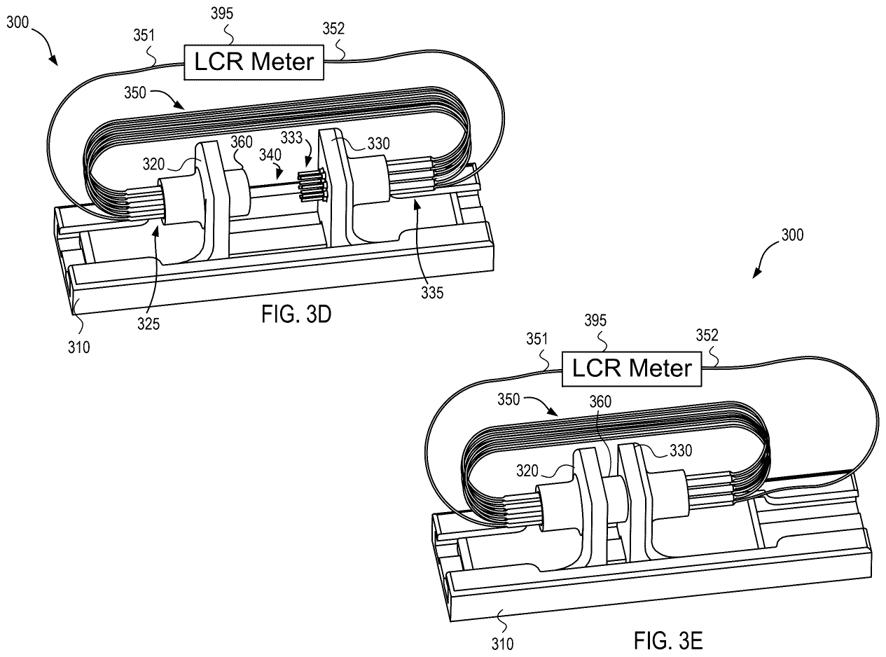

FIG. 3A is a perspective view of a manually actuated apparatus 300 with a set of conductors 350 positioned or located externally to the core-receiving region 340 (e.g. so that they remain external to an opening in the magnetic core once the magnetic core is placed with the core-receiving region 340). Each conductor 350 connects one contact probe of the first set of contact probes 323 to one contact probe of the second set of contact probes 333 via fixed connections to the outward conductor stacks of the left probe carrier 320 and the right probe carrier 330, respectively. The conductors 350 are configured such that when the contact probes 323 and 333 are in contact with each other in the closed measurement position, a series of loops or turns is formed around the magnetic core. A first electrical terminal 351 is connected to a contact probe of the first set of contact probes 323 of the left probe carrier 320 via a fixed connection to the corresponding outward conductor stack. A second electrical terminal 352 is connected to a contact probe of the second set of contact probes 333 of the right probe carrier 330 via a fixed connection to the corresponding outward conductor stack.

The first and second electrical terminals 351 and 352 are connected to an LCR meter 395. The slide-base support structure 310 may rest or be secured to a table or other workstation surface and include parallel guides to constrain the movement of the left probe carrier 320 and the right probe carrier 330. The left and right probe carriers 320 and 330 can be selectively translated toward one another to cause the contact probes 323 and 333 to meet inside the core-receiving region 340.

FIG. 3B is an enlarged detail view of a single contact probe 324 as might be retained in either probe carrier 320 or 330. The contact probe 324 includes a tubular barrel that may be, for example, press-fit, soldered, adhered, threaded, or otherwise secured within a probe carrier housing. The proximal end tip 326 of the contact probe 324 may include an internal compression spring and/or a conductive plunger that protrudes toward the core-receiving region 340. The spring biases the tip 326 outward so that when the probe carriers are translated to the closed measurement position, the tip 326 self-adjusts to meet the opposing contact probe of the other probe carrier. The spring-biased tip 326 may help the contact probe 324 to maintain a consistent contact force and low contact resistance with the opposing contact probe of the other probe carrier. The distal end tip 327 of the contact probe 324 extends outward from the probe carrier housing to form part of the outward conductor stack for connection to one of the fixed conductors 350 or one of the electrical terminals 351 or 352.

FIG. 3C depicts an example of a toroidal magnetic core 360 that may be tested with apparatus 300. The toroidal magnetic core 360 is annular and defines a central opening 365 that aligns with the inward-facing arrays of contact probes 323 and 333 when the toroidal magnetic core 360 is placed in the core-receiving region 340. During testing, the engaged contact probes 323 and 333 and the externally routed conductors 350 form multiple conductive loops that thread through opening 365 without requiring any wire to be manually wound through the aperture. As such, the apparatus 300 allows rapid, repeatable equivalent of winding multiple turns around the toroidal magnetic core 360. As the left probe carrier 320 and the right probe carrier 330 are translated to the closed measurement position, the contact probes 323 and 333 come into contact and simultaneously (e.g., concurrently) form multiple turns around the toroidal magnetic core 360 while minimizing handling time and avoiding damage to the core surface.

FIG. 3D depicts the manually actuated apparatus 300 of FIG. 3A with the toroidal magnetic core 360 positioned within the core-receiving region 340, according to one embodiment. The probe carriers 320 and 330 remain in the open loading position to permit the insertion of a magnetic core. As illustrated, the toroidal magnetic core 360 is positioned over the contact probes 323 of the left probe carrier 320. In various embodiments, the toroidal magnetic core 360 rests directly on the upper surface of the slide-base support structure 310, and its central opening 365 surrounds the inward-facing contact probes 323 of the left probe carrier 320. In this state, the right probe carrier 330, guided by the parallel rails of support structure 310, is spaced apart from the toroidal magnetic core 360 so the operator can verify that the toroidal magnetic core 360 is fully aligned and centered before actuation. The conductors 350 running between the outward conductor stacks 325 and 335 are ready to complete the series loops once the probe carriers close.

FIG. 3E shows the manually actuated apparatus 300 with the right probe carrier 330 translated laterally into the closed measurement position, according to one embodiment. The toroidal magnetic core 360 is positioned between the left probe carrier 320 and the right probe carrier 330. The opposing contact probes 323 and 333 compress their spring-loaded tips against one another inside opening 365, establishing simultaneous electrical and mechanical engagement around the full circumference of the toroidal magnetic core 360. The conductors 350 are fixed to the outward conductor stacks to bridge paired probe sets so that the engaged probes and conductors together define a predetermined number of conductive loops or turns through the opening 365 or aperture of the toroidal magnetic core 360. The loops terminate at the first and second electrical terminals 351 and 352, which are hard-wired to the LCR meter 395. Because the conductors 350 are routed entirely outside the aperture, no wire touches the core surface, preserving core coating integrity while delivering a rapid, repeatable multi-turn measurement path.

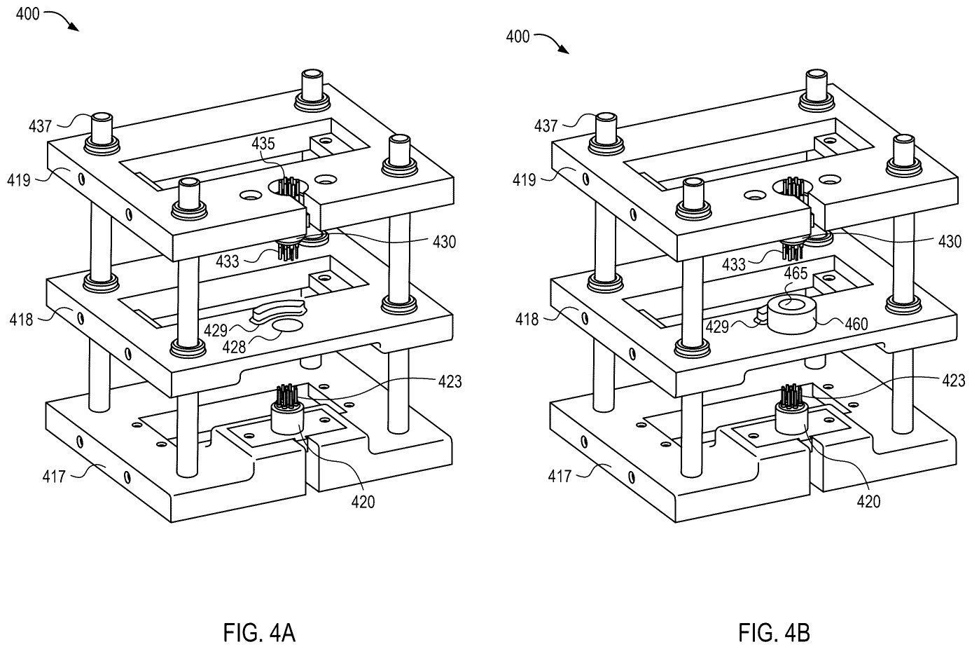

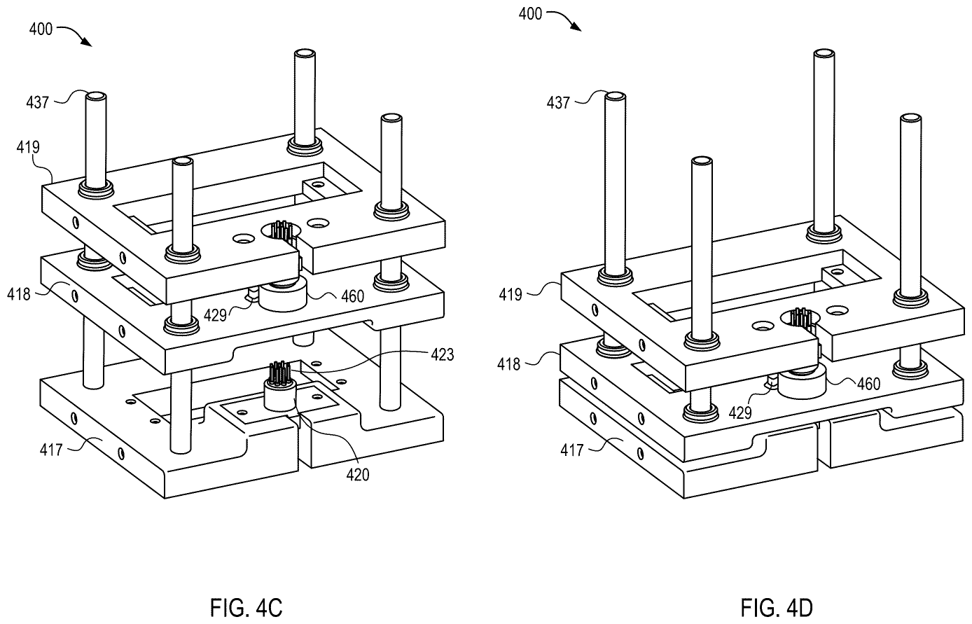

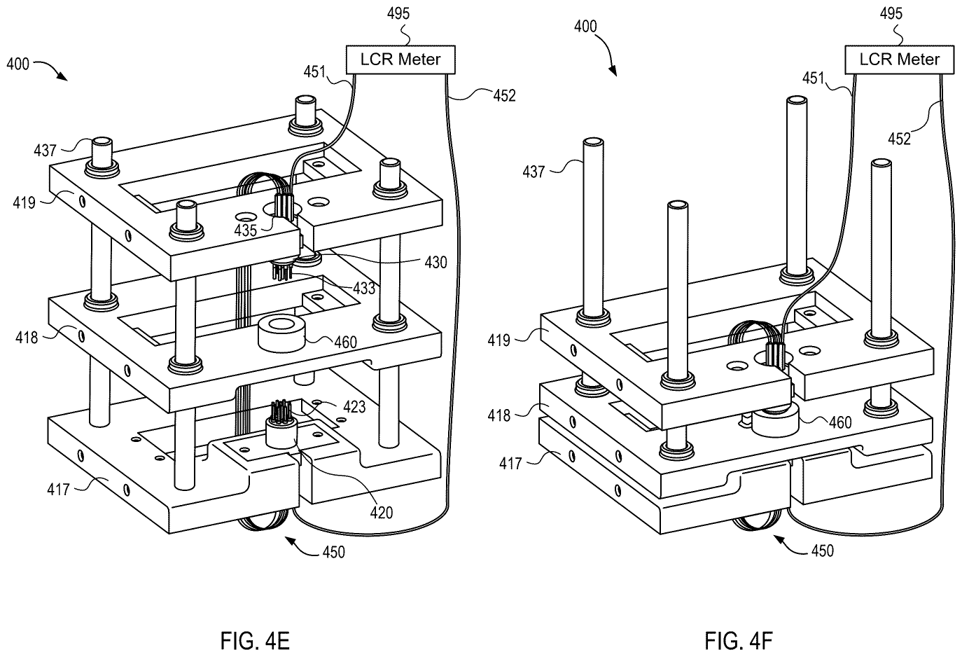

FIG. 4A is a perspective view of an automated apparatus 400 that may use manual, pneumatic, motorized (e.g., motor-driven), compressed air, hydraulic, or other actuation to translate two opposing probe carriers 420 and 430 relative to a core-receiving region. In the illustrated example, the lower probe carrier 420 is secured to a lower rectangular frame 417. The upper probe carrier 430 is secured to an upper rectangular frame 419. The core-receive region is defined between the two opposing probe carriers 420 and 430 and includes an aperture 428 in a middle rectangular frame 418. The middle rectangular frame 418 includes a nest plate 429 to receive and align a toroidal magnetic core. The nest plate 429 and/or the aperture 428 in the middle rectangular frame 418 may be adapted to accommodate and align magnetic cores of other shapes and sizes. When a toroidal magnetic core is placed on nest plate 429, its central opening aligns coaxially with the aperture 428 and the opposed arrays of contact probes 423 and 433.

The upper rectangular frame 419 and the middle rectangular frame 418 are translated downward toward the lower rectangular frame 417 to transition the two opposing probe carriers 430 between the open loading position and the closed measurement position. In the depicted embodiment, four guide columns 437 or other supports facilitate the movement of the upper rectangular frame 419 and middle rectangular frame 418 along a single axis. The guide columns 437 or other supports constrain the two opposing probe carriers 420 and 430 to linear, vertical motion.

The lower probe carrier 420 holds a first set of electrically conductive contact probes 423. Each probe may include a spring-biased mating end oriented toward the aperture 428 in the middle rectangular frame 418. An outward conductor stack (not shown) on the rear side of lower probe carrier 420 may provide solder-cup terminations for fixed conductors. Mounted opposite the lower probe carrier 420, the upper probe carrier 430 supports a second set of contact probes 433 that face contact probes 423 and an outward conductor stack 435.

FIG. 4B is a perspective view of the apparatus 400 of FIG. 4A with an example toroidal magnetic core 460 positioned in the core-receiving region. The core rests on the nest plate 429, which is fixed within the middle rectangular frame 418. The central opening 465 of the toroidal magnetic core 460 is coaxially aligned with the aperture 428 of the middle rectangular frame 418 and with the opposed arrays of spring-biased contact probes 423 and 433 held by the lower probe carrier 420 and the upper probe carrier 430, respectively.

In this view, the apparatus 400 remains in the open loading position. The upper rectangular frame 419 and the middle rectangular frame 418 have not yet translated downward along guide columns 437 toward the lower rectangular frame 417. Once actuation is initiated, the frameworks 419 and 418 will move along the guide columns 437, bringing the contact probes 423 and 433 into mechanical and electrical engagement inside the central opening 465 to establish the multi-turn conductive path, as described herein.

FIG. 4C illustrates the apparatus 400 in an intermediate position reached after the first stage of actuation or partial actuation. The upper rectangular frame 419 has translated partially downward along guide columns 437 so that the spring-biased contact probes 433 of the upper probe carrier 430 extend into the central opening 465 of the toroidal magnetic core 460. The probe tips remain spaced above the opposing contact probes 423 of the lower probe carrier 420, and the middle rectangular frame 418 with nest plate 429 has not yet moved from its initial height. The toroidal magnetic core 460 remains seated on nest plate 429 while only the upper probe carrier 430 engages the opening 465 of the toroidal magnetic core 460.

FIG. 4D shows the apparatus 400 in the closed measurement position, according to one embodiment. Both the upper rectangular frame 419 and the middle rectangular frame 418 have completed their downward travel along guide columns 437 toward the lower rectangular frame 417. The lower rectangular frame 417, along with the lower probe carrier 430, may remain stationary. The movement of the upper rectangular frame 419 and the middle rectangular frame 418 lowers the nest plate 429 and the toroidal magnetic core 460 until the central opening 465 surrounds the contact probes 423 of the lower probe carrier 420. Simultaneously, the spring-biased contact probes 433 of the upper probe carrier 430 are mechanically and electrically engaged with the corresponding contact probes 423 of the lower probe carrier 420 inside the opening 465 of the toroidal magnetic core 460. Together with fixed conductors (not shown) connected to the outward conductor stacks of the lower probe carrier 420 and upper probe carrier 430, the mated probes produce a series of conductive loops that provide multiple turns through the opening 465 or aperture of the toroidal magnetic core 460. The series of conductive loops may be connected to an external characterization device via the first and second electrical terminals, as described herein.

FIG. 4E depicts the apparatus 400 in the open loading position with a toroidal magnetic core 460 seated on nest plate 429 and with the measurement circuit fully wired. Fixed conductors 450 electrically interconnect the outward conductor stack (not visible) of the lower probe carrier 420 to the outward conductor stack 435 of the upper probe carrier 430. At their opposite ends, the conductors 450 converge to the first and second electrical terminals 451 and 452, which are connected to an LCR meter 495. Because the upper rectangular frame 419 and middle rectangular frame 418 have not yet been translated downward, the spring-biased contact probes 433 remain above probes 423, such that no probe-to-probe engagement exists within the central opening of the toroidal magnetic core 460. The circuit is, therefore, open even though the LCR meter 495 is already attached, and no readings or measurements can be made.

FIG. 4F shows the apparatus 400 in the closed measurement position. The upper rectangular frame 419 and middle rectangular frame 418 are moved downward along guide columns 437 until the toroidal magnetic core 460 surrounds the contact probes 423 and 433, with the upper contact probes 433 meeting the lower contact probes 423. The connection between the contact probes 423 and the contact probes 433 closes the electrical path defined by conductors 450 to simultaneously and rapidly form a predetermined series of conductive loops that create multiple turns through the toroidal magnetic core 460. The loops formed by the conductors 450 terminate at electrical terminals 451 and 452, which are coupled to the LCR meter 495. With the circuit closed, the LCR meter 495 can determine inductance, resistance, and/or other selected parameters of the toroidal magnetic core 460.

According to any combination of the various embodiments described herein, an LCR meter or other magnetic core characterization device operates to determine one or more parameters or characteristics of a magnetic core. In various embodiments, the magnetic core characterization device may include various hardware, software, and/or firmware components or modules to implement specific electrical measurements and/or computations. In some embodiments, the magnetic core characterization device may utilize user-specified information and/or pre-programmed information about a measured magnetic core, such as dimensions, material compositions, coatings, existing wire turns on the magnetic core, and the like. Moreover, the accuracy and an estimate of the error in measurement can be calculated based on these parameters and the number of turns created by the apparatus (e.g., with 10 contact probes on each probe carrier, nine turns can be formed within a magnetic core).

In various embodiments, a magnetic core characterization device calculates an inductance factor (A_{L}) using the following equation:

$${A}_{L} = \frac{{L}_{S}}{{N}^{2}} [ H / Turns ] ,$$

where L_{S}[H] represents the measured inductance in Henries, and N is the number of turns. Thus, a magnetic core characterization device can calculate the inductance factor based on the known number of turns created by the apparatus and the measured inductance of the core. The system may be pre-programmed with information identifying the material in use, and/or the information may be specified by the operation.

For a given material and known properties thereof, the inductance factor can be calculated using the following equation:

$${A}_{L} = ( \frac{{μ}_{0} \times {μ}_{r} \times {A}_{C}}{l} ) [ H / Turns ] ,$$

where μ₀ represents the permeability of free space (4π*10⁻⁷), l represents the mean magnetic path length, A_{C} represents the effective cross-sectional area and μᵣ represents the initial relative permeability.

The effective cross-sectional area (A_{C}) can be calculated by using the equation:

$${A}_{c} = ( \frac{( OD - ID )}{2} ) * ( Height ) [ {m}^{2} ] ,$$

where OD represents the outside diameter, ID represents the inside diameter, and Height represents the height. Given example values as follows:
OD=0.0222 [m]
ID=0.0135 [m]
Height=0.0102 [m]

The effective cross-sectional area (A_{C}) can be calculated as:
A_{C}=0.000044166 [m²]

The mean magnetic path length (l) can be calculated by using the equation:

$$l = ( \frac{π * ( OD - ID )}{ln ( \frac{OD}{ID} )} ) [ m ]$$

Using the same example values, the mean magnetic path length (l) can be calculated as:
l=0.055023 [m]

By substituting

$$\frac{{L}_{S}}{{N}^{2}}$$

into

$${A}_{L} = ( \frac{{μ}_{0} \times {μ}_{r} \times {A}_{C}}{l} ) ,$$

the system can solve for μᵣ in the following equation:

$$\frac{{L}_{S}}{{N}^{2}} = ( \frac{{μ}_{0} * {μ}_{r} * {A}_{C}}{l} ) ,$$

such that μᵣ is expressible as:

$${μ}_{r} = \frac{{L}_{S} * l}{{N}^{2} * {μ}_{0} * {A}_{C}} [ \frac{H}{m} ]$$

The system may use the magnetic core characterization device to measure the inductance (L_{S}) of one or more magnetic cores. Using an example apparatus that creates nine turns within the magnetic core (N=9) and an example inductance measurement of L_{S-Core}=254 μH, the system may calculate the initial relative permeability μᵣ using the equation above as approximately: μᵣ=3108 [H/m]. Returning to the inductance factor equation, we can solve for A_{L} as:

A_{L}=3.136 [μH/Turns]:

The system can use the calculated inductance factor (A_{L}) for the core material to estimate the secondary inductance of the magnetic core when the turns of wire are increased by several thousand (e.g., 3000) for real-world use, using the following equation:

L_{S}=N²(A_{L})[H], where L_{S} represents the estimated secondary inductance of the magnetic core with N turns. Using the example values above, the secondary inductance of the magnetic core with 3000 turns is 28.22 [H]. The error of the estimated secondary inductance can be lowered by using more than nine turns for measurements. For example, the apparatuses described herein may include 10, 20, 30, or more pins or “contact probes” to reduce the measurement error.

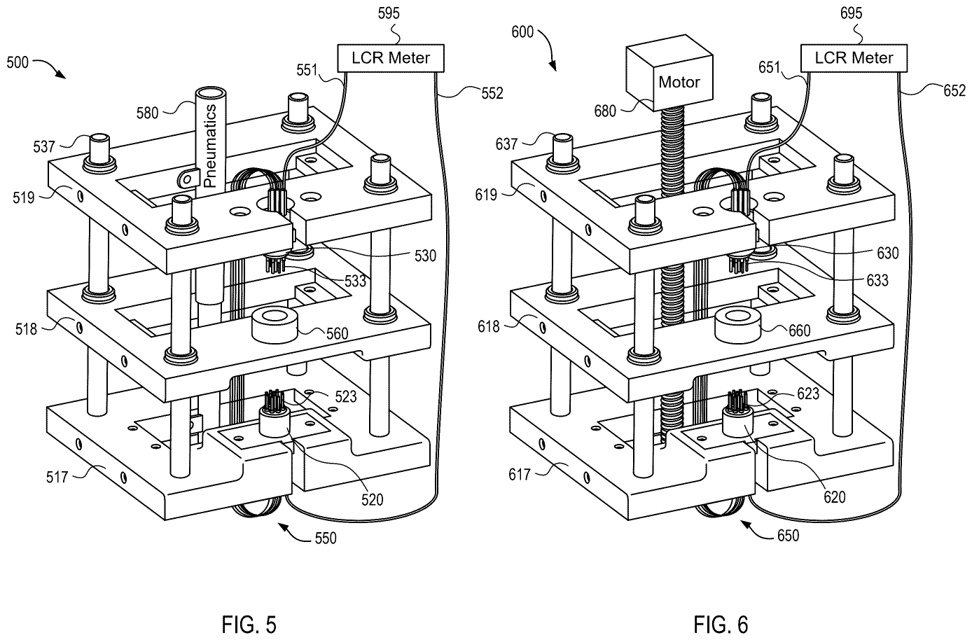

FIG. 5 depicts an automated apparatus 500 that corresponds functionally to the apparatus 400 described in conjunction with FIG. 4E, but employs a pneumatic actuation subsystem. A toroidal magnetic core 560 rests on a nest plate within the aperture of the middle rectangular frame 518 while the apparatus is in the open loading position. The fixed conductors 550 remain connected to outward conductor stacks of the lower probe carrier 520 and the upper probe carrier 530, respectively, and terminate at electrical terminals 551 and 552, which are coupled to an LCR meter 595. A double-acting pneumatic cylinder 580 is anchored to the lower rectangular frame 517 and upper rectangular frame 519. The double-acting pneumatic cylinder 580 translates the upper and middle frameworks along guide columns 537. Pressurizing the rod-side port lowers frameworks 519 and 518 so that contact probes 533 engage opposing probes 523 inside the opening of toroidal magnetic core 560, thereby creating the multi-turn conductive path without manual intervention. Reversing the airflow returns the fixture to the open position for unloading and reloading another toroidal magnetic core 560.

FIG. 6 shows an automated apparatus 600 that utilizes a rotary drive assembly rather than pneumatics to achieve the same motion sequence. A motor and worm-gear reducer 680 may, for example, drive a lead screw threaded through a nut affixed to the upper rectangular frame 619. Rotation of the lead screw draws the upper frame 619 and the middle frame 618 downward along guide columns 637 toward the lower rectangular frame 617. This movement brings the contact probes 633 of the upper probe carrier 630 into mechanical and electrical engagement with corresponding probes 623 of the lower probe carrier 620 inside the opening of a toroidal magnetic core 660. Conductors 650 are coupled to outward conductor stacks and electrical terminals 651 and 652, which remain continuously connected to an LCR meter 695. The illustrated embodiment provides a motor-based actuation system to facilitate automated, repeatable core characterization cycles of any number of toroidal magnetic cores.

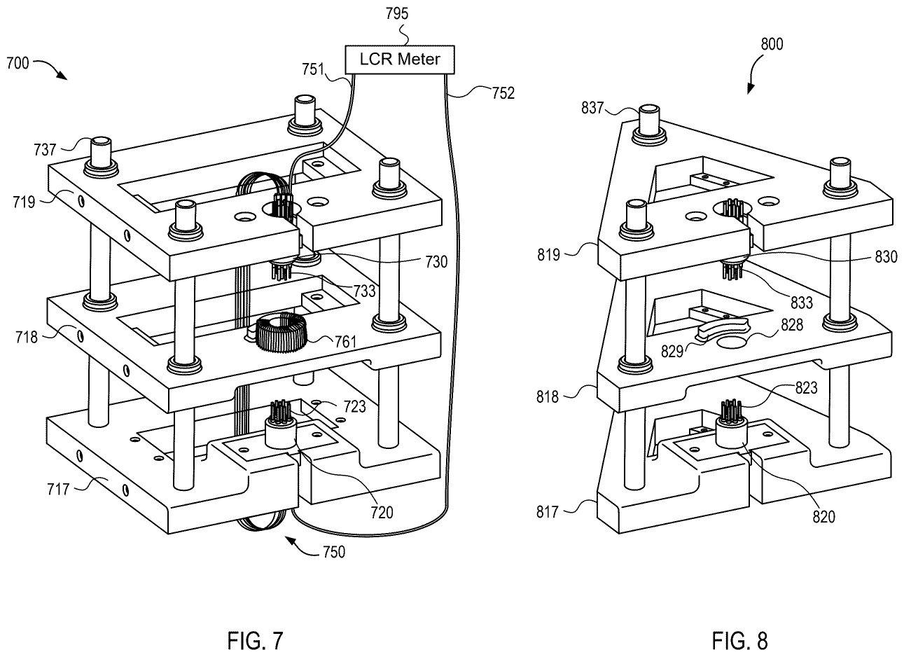

FIG. 7 illustrates an apparatus 700 to characterize a toroidal magnetic core 761 that has already been wound with a production winding, according to one embodiment. In some instances, the production winding may include several thousand turns. The apparatus 700 does not use the production windings to test the toroidal magnetic core 761. Instead, the apparatus still uses the windings created by the connected contact probes 723 and 733. The core 761 sits on the nest plate in the middle rectangular frame 718. The production winding occupies the outer surface of the toroidal magnetic core 761 and does not obstruct the central opening thereof. Accordingly, the opposed arrays of contact probes 723 and 733 extend into the opening when the fixture moves to the closed measurement position.

The lower probe carrier 720 is secured to the lower rectangular frame 717 and retains the first set of contact probes 723, while the upper probe carrier 730 is secured to the upper rectangular frame 719 and supports the second set of contact probes 733. Outward conductor stacks on the rear sides of probe carriers 720 and 730 are connected by fixed conductors 750, which terminate at first and second electrical terminals 751 and 752 coupled to an LCR meter 795. As in previously described embodiments, the guide columns 737 constrain frameworks 719 and 718 to linear motion toward and away from frame 717 so that the probes 723 and 733 meet inside the opening of the toroidal magnetic core 761 without contacting or disturbing the production windings. Engagement of the probes, together with conductors 750, forms the predefined series of conductive loops through the core aperture. The LCR meter 795 measures the inductance and related parameters of the already-wound core 761 without removing or altering the production winding.

FIG. 8 illustrates an apparatus 800 that operates like the previously described fixtures but employs triangular frameworks 817, 818, and 819 and only three guide columns 837, according to one embodiment. The lower triangular frame 817 anchors a lower probe carrier 820 that holds the first set of contact probes 823 (e.g., spring-biased contact probes). The upper triangular frame 819 supports an opposing probe carrier 830 with a second set of contact probes 833 and an outward conductor stack for connection to conductors to form the loops (not shown to avoid obscuring the drawing). The middle triangular frame 818 spans the three guide columns 837 and contains a circular aperture 828 with a nest plate 829 sized to receive a toroidal magnetic core. The guide columns 837 are positioned at the vertices of the triangular framework, constraining the upper and middle frameworks to linear motion toward and away from the lower frame along a common axis.

As in other embodiments, fixed conductors (not shown) can be used to join the outward conductor stack on the lower probe carrier 820 to the outward conductor stack on the upper probe carrier 830. The fixed conductors operate to create a series of loops or turns through the toroidal magnetic core before terminating at the first and second electrical terminals configured to be connected to an LCR meter or other measurement device. In the open loading position, the upper and middle frameworks 818 and 819 are separated from the lower framework 817 so that the central opening of a toroidal magnetic core aligns with the contact probes 823 and 833. Actuation, which may be pneumatic, motorized, or manual, drives the upper frame 819 and the middle frame 818 downward along the guide columns 837 until the contact probes 833 engage the contact probes 823. The engaged contact probes and conductors form multiple conductive loops through the aperture for rapid electrical characterization without hand-winding test wire.

It is appreciated that two or more of the systems, subsystems, components, modules, etc., that are described herein may be combined as a single system, subsystem, module, or component. Moreover, many systems, subsystems, components, and modules described herein may be duplicated or further divided into discrete systems, subsystems, components, or modules to perform subtasks of those described herein. Any of the embodiments described herein may be combined with any combination of other embodiments described herein.

The components of some of the disclosed embodiments are described and illustrated in the figures herein. Many portions thereof could be arranged and designed in a wide variety of different configurations. Furthermore, the features, structures, and operations associated with one embodiment may be applied to or combined with the features, structures, or operations described in conjunction with another embodiment. In many instances, well-known structures, materials, or operations are not shown or described in detail to avoid obscuring aspects of this disclosure. Some illustrations are provided in a block diagram format to illustrate a general configuration and may not be drawn to scale. The right to add any described embodiment or feature to any one of the figures and/or as a new figure is explicitly reserved.

This disclosure has been made with reference to various examples and embodiments, including the best mode. However, those skilled in the art will recognize that changes and modifications may be made to the exemplary embodiments without departing from the scope of the present disclosure. While the principles of this disclosure have been shown in various embodiments, many modifications of structure, arrangements, proportions, elements, materials, and components may be adapted for a specific environment and/or operating requirements without departing from the principles and scope of this disclosure. These and other changes or modifications are intended to be included within the scope of the present disclosure, along with every permutation of the claims filed herewith.

What is claimed:

1. An apparatus for magnetic core characterization, comprising:
a support structure to support a magnetic core within a core-receiving region;
a first probe carrier supporting a first set of electrically conductive contact probes on a first side of the core-receiving region, each contact probe of the first set of contact probes including a mating end oriented toward the core-receiving region;
a second probe carrier supporting a second set of electrically conductive contact probes on a second, opposite side of the core-receiving region, each contact probe of the second set of contact probes including a mating end oriented toward the core-receiving region and opposing a corresponding mating end of a contact probe of the first set of contact probes;
a first electrical terminal connected to a contact probe of the first set of contact probes;
a second electrical terminal connected to a contact probe of the second set of contact probes;
a plurality of conductors positioned external to an opening in the magnetic core, each conductor connecting one contact probe of the first set of contact probes to one contact probe of the second set of contact probes; and
an actuation mechanism configured to facilitate translation of the first and second probe carriers between:
(i) an open loading position in which the opposed mating ends of the first and second sets of contact probes are spaced apart to permit insertion of the magnetic core within the core-receiving region, and
(ii) a closed measurement position in which the opposed mating ends of first and second sets of contact probes mechanically engage one another through the opening in the magnetic core and, together with the conductors, form a series of conductive loops that produce multiple turns through the opening in the magnetic core, the loops terminating at the first and second terminals.

2. The apparatus of claim 1, wherein at least one of the contact probes is spring-biased outward to facilitate electrical engagement with an opposing contact probe.

3. The apparatus of claim 1, wherein the magnetic core comprises a toroid.

4. The apparatus of claim 1, wherein the actuation mechanism comprises a manually operated slide to facilitate translation of the first and second probe carriers between the open loading position and the closed measurement position.

5. The apparatus of claim 1, wherein the actuation mechanism comprises a pneumatic cylinder to facilitate translation of the first and second probe carriers between the open loading position and the closed measurement position.

6. The apparatus of claim 1, wherein the actuation mechanism comprises a motor-driven actuator to facilitate translation of the first and second probe carriers between the open loading position and the closed measurement position.

7. The apparatus of claim 1, further comprising:
a first framework to support the first probe carrier with the first set of contact probes; and
a second framework to support the second probe carrier with the second set of contact probes.

8. The apparatus of claim 7, wherein the first and second frameworks are configured to translate along a plurality of supports to translate the first probe carrier toward the second probe carrier.

9. The apparatus of claim 8, wherein the core-receiving region comprises a middle framework to mechanically support the magnetic core between the first framework and the second framework.

10. The apparatus of claim 8, wherein the second framework with the second probe carrier remains stationary.

11. The apparatus of claim 7, wherein each of the first and second frameworks comprises one of: a rectangular framework, a triangular framework, and a circular framework.

12. The apparatus of claim 1, wherein the first and second electrical terminals are configured to be connected to a magnetic core characterization device.

13. A method for characterizing a magnetic core, comprising:
positioning the magnetic core within a core-receiving region located between a first probe carrier and a second, opposing probe carrier, the first and second probe carriers respectively supporting first and second sets of electrically conductive contact probes having mating ends oriented toward the core-receiving region;
translating at least one of the probe carriers from an open loading position, in which the opposed mating ends are spaced apart, to a closed measurement position, in which the opposed mating ends mechanically engage one another through an opening in the magnetic core;
electrically interconnecting, with conductors located external to the opening in the magnetic core, each contact probe of the first set to a corresponding contact probe of the second set such that the engaged contact probes and conductors together form a series of conductive loops that produce multiple turns through the opening of the magnetic core, the series of conductive loops terminating at first and second electrical terminals;
coupling the first and second electrical terminals to a magnetic core characterization device; and
measuring at least one electrical parameter of the magnetic core with the magnetic core characterization device.

14. The method of claim 13, wherein at least one of the contact probes is spring-biased outward to facilitate mechanical engagement with an opposing contact probe.

15. The method of claim 13, wherein the magnetic core is toroidal.

16. The method of claim 13, wherein translating at least one of the probe carriers from the open loading position to the closed measurement position is performed with a manually operated slide.

17. The method of claim 13, wherein translating at least one of the probe carriers from the open loading position to the closed measurement position is performed with a pneumatic cylinder.

18. The method of claim 13, wherein translating at least one of the probe carriers from the open loading position to the closed measurement position is performed with a motor-driven actuator.

19. The method of claim 13, further comprising supporting the first and second probe carriers on respective first and second frameworks, and wherein translating at least one of the probe carriers from the open loading position to the closed measurement position comprises translating at least one of the frameworks along supports toward the other framework.

20. The method of claim 19, further comprising supporting the magnetic core on a middle framework positioned between the first and second frameworks while translating the probe carriers.

21. The method of claim 13, wherein the electrical parameter comprises an inductance of the magnetic core.
